(19) United States
(12) Patent Application Publication
(10) Pub. No.: US 2006/0183270 A1
(43) Pub. Date: Aug. 17, 2006

(54) Tools and methods for forming conductive bumps on microelectronic elements

(75) Inventor: Giles Humpston, Aylesbury (GB)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/351,591

(22) Filed: Feb. 10, 2006

Related U.S. Application Data
(60) Provisional application No. 60/652,615, filed on Feb. 14, 2005.
(60) Provisional application No. 60/652,539, filed on Feb. 14, 2005.

(51) Int. Cl. H01L 21/50; H01L 21/48

(52) U.S. Cl. 438/106

(57) ABSTRACT

A method of making a microelectronic assembly includes providing a microelectronic element having a front face and contact pads accessible at the front face, providing a dispensing tool containing a molten metal and having a discharge port for dispensing the molten metal, and aligning the discharge port of the dispensing tool with one of the contact pads of the microelectronic element. A mass of the molten metal is dispensed through the discharge port and onto the one of the contact pads of the microelectronic element; and ultrasonic waves are applied to the mass of molten metal during the dispensing step for facilitating wetting of the mass of molten metal with the one of the contact pads of the microelectronic element.

### CROSS REFERENCE TO RELATED APPLICATIONS

The present application claims benefit of U.S. Provisional Application No. 60/652,539, filed Feb. 14, 2005, and U.S. Provisional Application No. 60/652,615, filed Feb. 14, 2005, the disclosures of which are hereby incorporated by reference herein.

### FIELD OF THE INVENTION

The present invention is generally directed to making microelectronic packages, and is more particularly directed to forming under bump metallurgy (UBM) on microelectronic packages.

### BACKGROUND OF THE INVENTION

Microelectronic chips are thin, flat bodies having oppositely facing front (active) and rear surfaces. A chip has contacts on its active surface that are electrically connected to circuits within the chip. In accordance with “flip-chip” technology, a chip is mounted on a substrate with its active face directed toward the substrate. Electrical interconnections between the chip and substrate are established by providing conductive bumps on the active surface of the chip, which make contact with conductive pads on the substrate. The conductive bumps are often made of a solder.

Typically, an initial step in the flip-chip process involves applying multi-layered metallization to pads on the chip to render the pads wettable by molten solder. This part of the structure is commonly referred to as the “under bump metal” (UBM), the composition and formation of which is well known in the art.

The UBM is then overcoated with solder at selected sites. Known techniques for this step include vapor phase deposition, electroplating, and direct application. Among the direct application techniques is included the placement of small solder spheres, either individually or in a ganged operation.

Referring to FIG. 1, a well-known method of assembling a semiconductor chip 10 to a substrate 12, such as a printed circuit board (PCB), uses an array of solder spheres 14. The connection points on the PCB, commonly referred to as “lands” 16, are typically made of copper or a combination of metals such as nickel overlaid with a coating of gold. The selection of copper and the common metal combinations is based upon a number characteristics including solderability. As a result, when reflowed, the solder spheres used to attach the conductive bond pads 18 of the semiconductor chip 10 to the PCB 12 will readily wet, spread and adhere to the lands 16 on the PCB 12.

The ease with which the lands 16 on the PCB 12 can be soldered does not generally apply, however, to the connection points on the semiconductor chip 10. These connection points, often referred to as “bond pads” 18, are usually made of aluminum containing low percentages of other metals, notably silicon. Even for a modern semiconductor chip employing copper wiring traces, the bond pads 18 are usually finished with a thin layer of aluminum.

A fundamental difficulty with using aluminum bond pads 18 on the semiconductor chip 10 is that aluminum is an extremely difficult metal to solder. This stems from the native film of alumina that will rapidly grow to cover any aluminum surface when the metal is exposed to air. Alumina is both chemically stable and mechanically robust, making it difficult to displace, dissolve or chemically reduce. If the alumina film can be removed, however, direct metallic bonding between the aluminum and the solder is possible so an intervening UBM is no longer required.

A known method of apply molten solder to a flat substrate containing cavities is C4NP. This equipment consists of a tool that contains a reservoir of molten solder under slight pressure. The reservoir is connected to a narrow slot at the bottom of the tool that is slightly shorter in length than the width of the substrate. The tool is placed in contact with the substrate, to make a seal and then drawn over the substrate. As the slot passes over a cavity in the substrate, the pressure of the solder results in filling of the cavity. The bond pads on a silicon wafer are usually recessed with respect to other surface features i.e. they may be considered as shallow cavities.

Although the C4NP tool can be used to apply a thin film of solder to the bond pads on a wafer that has had a UBM applied. It will not work where no UBM is present, because of the alumina film covering the bond pad. A previously disclosed, the oxide film renders the aluminum un-solderable because it prevents direct metallic contact between the aluminum and the solder. If the aluminum does not have an oxide skin when the solder contacts the bond pads, however, then the bond pads will be left with a thin shim of solder on the surface. Attachment of solder spheres to these solder-wetted bond pads for flip chip attach is then a straightforward exercise.

The problem of soldering aluminum has been recognized almost since aluminum was first produced commercially at the beginning of the 20th Century. As an industrial metal, one of the first widespread uses for aluminum was as an aircraft skins. Because of the propensity for aluminum to oxidize, high strength aluminum alloys cannot be joined by welding, brazing or soldering. Thus, riveting typically joins the skin panels on aircraft, which adds weight and minimizes strength.

During World War II, there was a need to apply patches to cover bullet holes in the aluminum skin of aircraft. It was found that if the area surrounding the hole and the patch were heated to soldering temperatures and rubbed together, the mechanical action would locally disrupt the oxide skin. A solder in the joint gap could then wet the aluminum through the fissures and displace the oxide by undermining it, resulting in a strong joint that could be made completely without flux. The mechanical rubbing action was subsequently refined by the substitution of ultrasonic transducers that could be electrically controlled. It was believed that the ultrasonic transducers developed a pressure wave in the solder that broke up the oxide by cavitations.

Later, ultrasonic soldering irons were developed and are still in commercial use today. Ultrasonic transducers have also been incorporated into wave soldering equipment. The sonodes, which are an integral part of the wave generation tooling, impart sonic action while the PCB travels through the wave.

In the semiconductor industry, one solution to the problem of solderability of aluminum has been to remove the aluminum skin and replace it with metals that are nobler in character and hence readily solderable. Because these metals lie underneath the solder sphere, this type of assembly is commonly called under bump metal (UBM) or sometimes bi-layer metal (BLM), depending on the detail of the structure. When UBM is formed, the metals may be deposited by either wet plating or vapor phase deposition.

As is well known to those skilled in the art, UBM fulfills at least three functions: 1) it adheres to the underlying aluminum and makes ohmic contact with the underlying aluminum, 2) it is wettable by the solder sphere, but not significantly soluble in the solder sphere, and 3) it acts as a barrier layer to diffusion of silicon into the solder and vice versa. Because no single metal can satisfy all three requirements listed above, the UBM is often a stack of several metals.

The foundation or strike layer of the UBM should possess the attributes of being able to bond strongly to the aluminum bond pad, provided that the surfaces are clean and make ohmic contact to it. For this reason the choice is usually an active metal such as titanium, chromium, or nickel, or often zinc where wet chemistry is being used for the deposition process. Ideally, the foundation metal will restrict interdiffusion between the solder and underlying material. Where this is insufficient, a barrier layer will be designed into the metallization. Depending on the estimated service life and the temperatures to which the joint will be exposed, the required effectiveness of the barrier layer will vary. Copper and nickel are adequate for many applications, while platinum and titanium-tungsten alloys are used for more demanding environments. Titanium-tungsten alloys are themselves often multi-layer structures comprising titanium-tungsten/titanium-tungsten oxy-nitride/titanium tungsten to further improve the resistance to diffusion. Most barrier metals will oxidize when exposed to air, which will impede wetting and spreading by the molten solder. To overcome this problem, the metallization stack is usually finished with a thin layer of gold, or sometimes silver or a metal from the platinum group. Gold is often applied as a finish to platinum group metals as a yellow metal is easier to inspect visually for defects than a white metal and most solders generally spread better on gold than platinum group metals.

A review of the relevant literature indicates that there are dozens of UBM's for different applications, because no metallization is universally compatible with all solders and substrates. UBM's that come close to having a universal application tend to be more expensive to fabricate. Thus, there is an incentive to develop alternative UBM's for specific applications.

Irrespective of which UBM is selected, the application of UBM to the semiconductor chip or wafer usually entails a long sequence of process steps, each of which has an associated cost and yield penalty.

One known method for applying solder bumps over UBM on a chip or wafer has been achieved with a process known as Controlled Collapse Chip Connection New Process or C4NP, developed by International Business Machines. See IBM Research & IBM Systems and Technology Group presentation entitled “C4NP—Technology For Lead-Free Wafer Bumping,” September 2004, the disclosure of which is hereby incorporated by reference herein. Generally, C4NP is a process involving the indirect application of solder spheres to a wafer that has had UBM applied. The process works with virtually any solder composition and sphere size, is quick to perform, achieves high precision of sphere placement and is materials and energy efficient.

Referring to FIG. 2, using the C4NP tools and process, controlled amounts of molten solder 20 are applied to a glass substrate plate 22. The glass substrate plate is not wettable by solder and is matched in thermal expansion coefficient to the semiconductor wafer or chip to which the solder is eventually applied. Several types of glass may be used. The glass plate 22 has formed in it an array of closed cavities 24, one corresponding to each location on the wafer or chip where a solder sphere is desired. A tool 26 containing the molten solder 20 under pressure is wiped over the glass plate 22, so that each cavity is left filled with the metal 20.

Referring to FIG. 3A, the plate is then inverted, and placed on the wafer or chip so that the metal in the cavities of the plate is aligned with the contact pads of the wafer. Referring to FIG. 3B, the plate holding the metal and the wafer are clamped together. Referring to FIG. 3C, the solder or metal in the cavities of the plate is reflowed a second time so that it wets and bonds to the UBM on the wafer and dewets from the glass plate. Referring to FIG. 3D, the clamp and the plate are then removed. At the end of the process, as shown in FIG. 3E, the wafer is populated with an array of solder spheres and the glass plate is left clean, ready for reuse.

In spite of the above advances, there remains a need for improved tools and methods for connecting conductive masses, such as solder spheres, with the conductive pads on semiconductor wafers and semiconductor chips.

### SUMMARY OF THE INVENTION

This invention disclosure describes a potentially low cost under bump metallurgy (UBM) and a method of creating the structure. The method assumes the availability of equipment having many common features with that utilized for C4NP. Indeed, when combined with C4NP to transfer solder bumps to a wafer, the entire bumping process can be accomplished without masks, wet chemistry or vapor phase deposition systems. The fusible UBM structure is compatible with most low and high melting point, indium and tin-based solders.

In certain preferred embodiments of the present invention, a method of making a microelectronic assembly includes providing a microelectronic element having a front face and contact pads accessible at the front face, dispensing a mass of molten metal such as molten solder onto one of the contact pads of the microelectronic element, and applying ultrasonic energy or waves to the mass of molten metal during the dispensing step for facilitating wetting of the mass of molten metal with one of the contact pads of the microelectronic element.

The microelectronic element may be a semiconductor wafer, a semiconductor chip or a circuitized substrate. The frequency of the ultrasonic waves applied to the molten metal may be modified so that different frequency waves are applied to the molten metal during dispensing.

The method may include providing a dispensing tool, such as a C4NP-like tool, containing a molten metal. The tool preferably has a discharge port for dispensing the molten metal. The method may also include aligning the discharge port of the dispensing tool with the one of the contact pads of the microelectronic element and dispensing the mass of the molten metal through the discharge port and onto the one of the contact pads of the microelectronic element. The dispensing step may be repeated for dispensing a mass of molten metal atop each of the contact pads or a plurality of the contact pads of the microelectronic element.

In certain preferred embodiments, the dispensing tool includes a chamber for holding the molten metal, the chamber being in communication with the discharge port, and an ultrasonic transducer coupled with the chamber for producing the ultrasonic waves. A planar element may be provided over the front face of the microelectronic element. The planar element preferably has at least one opening extending therethrough. The at least one opening in the planar element may be aligned with one of the contacts of the microelectronic element, and the discharge port of the dispensing tool may be aligned with the at least one opening in the planar element. In preferred embodiments, the planar element is connected with the microelectronic element. In other preferred embodiments, the planar element is connected with the dispensing tool. The planar element may have a plurality of openings extending therethrough, with one opening for each conductive pad on a wafer.

The ultrasonic energy or waves are preferably applied to the molten solder at a frequency of about 20 KHz-100 MHz. In preferred embodiments, the ultrasonic transducer generates ultrasonic waves having a frequency of about 20 KHz-100 MHz. The ultrasonic transducer may be connected with the dispensing tool and operated during the dispensing step. In certain preferred embodiments, the ultrasonic transducer is coupled with the discharge port of the dispensing tool.

In certain preferred embodiments, the dispensing tool has a C4NP-like configuration, such as the C4NP system disclosed by International Business Machines, and at least one ultrasonic transducer coupled with the dispensing tool. The at least one ultrasonic transducer preferably includes a controller for modifying the frequency of the ultrasonic waves generated by the at least one ultrasonic transducer.

The contact pads on the microelectronic element may include aluminum. The contact pads may also include a low melting point metal applied atop the aluminum pads. The low melting point metal may be a pure metal or a fusible alloy such as an alloy made of indium, tin, lead, cadmium or zinc.

Although not limited by any particular theory of operation, it is believed that the present invention provides an efficient and low cost method of making a microelectronic assembly using a modified IBM C4NP tool set and using specially formulated low melting point alloys. As is known to those skilled in the art, aluminum bond pads are not normally wettable by solder because of the presence of an alumina film surface. The present invention seeks to solve this problem by using ultrasonic energy for breaking up the oxide film by mechanical action, thereby facilitating direct metallic bonding without using flux. Thus, the present invention equips a C4NP tool or a C4NP-like tool with an ultrasonic transducer so that direct wetting of aluminum bond pads by a low melting point alloy becomes possible. In certain preferred embodiments, the low melting point alloy must be either fusible or rendered so through further alloying at the temperature at which the solder sphere is attached. As a result, the oxide skin on the fusible alloy can therefor be physically displaced. It has been determined that conventional fluxes will not work if the low melting point alloy contains even ppm additions of aluminum. The low melting point alloy should preferably contain a suitable mix of major and minor elements to minimize the solubility of aluminum and acts as a diffusion barrier to intermixing of species in the solder with those on the wafer and vice versa. Preferred low melting point alloys include tin, zinc-based alloys, indium, bismuth and cadmium based alloys.

In other preferred embodiments of the present invention, a method of making a microelectronic assembly includes providing a microelectronic element having a front face and contact pads accessible at the front face, providing a dispensing tool containing a molten metal such as molten solder and having a discharge port for dispensing the molten metal, and aligning the discharge port of the dispensing tool with one of the contact pads of the microelectronic element. The method preferably includes dispensing a mass of the molten metal through the discharge port and onto one of the contact pads of the microelectronic element, and applying ultrasonic waves to the mass of molten metal during the dispensing step for facilitating wetting of the mass of molten metal with one of the contact pads of the microelectronic element.

The method may also include pressurizing the molten metal within the dispensing tool prior to the dispensing step. The dispensing tool preferably includes a chamber for holding the molten metal, the chamber being in communication with the discharge port, and an ultrasonic transducer in contact with the dispensing tool for producing ultrasonic waves in the chamber. A planar element may be provided over the front face of the microelectronic element, the planar element having at least one opening extending therethrough. The at least one opening in the planar element may be aligned with one of the contacts on the microelectronic element, and the discharge port of the dispensing tool is aligned with the at least one opening extending through the planar element.

The method may also include connecting an ultrasonic transducer with the dispensing tool, and operating the ultrasonic transducer during the dispensing step for applying ultrasonic waves to the mass of molten metal. The ultrasonic transducer may be coupled with the discharge port of the dispensing tool or to another part of the dispensing tool.

In other preferred embodiments of the present invention, a C4NP tool or a tool similar to a C4NP tool may be used to disrupt, remove, dissolve or chemically reduce the aluminum oxide layer on an aluminum bond pad to facilitate wetting and bonding by a solder alloy or molten metal. As described herein, in certain preferred embodiments, the solder alloy wetted onto the bond pads is not a standard solder alloy but contains other elements for modifying the reaction between a standard tin-based solder and an aluminum bond pad. In one particular preferred embodiment, the thin film of solder applied to the bond pads may be a zinc-based solder containing nickel and cobalt, to restrict inter-diffusion between the metals on the wafer and those in the flip chip solder spheres.

In certain preferred embodiments of the present invention, the aluminum bond pads on the semiconductor wafer are manufactured to normal industrial standards, with the bond pads having smooth surfaces and being produced to high and consistent standards in terms of the metals and process conditions used. As a result, the alumina skin formed on the bond pads due to oxidation will generally be thin, probably less than 0.1 m thick and be of reproducible composition. Maintaining the consistency of the thickness and composition of the alumina skin will simplify the removal of the alumina skin and assist in ensuring consistent results.

The present invention can be sub-divided depending on whether its implementation can be achieved relatively easily on an existing C4NP tool having a single chamber or whether the C4NP tool requires multiple chambers, major modification or an entirely new equipment set. Generally, the methods disclosed herein are presented in order of the quality of seal that should be achieved between the C4NP tool and the wafer. Thus, modified solder alloys are presented first as it unlikely that changes will be required. Various aqueous and organic liquid processes are considered next, followed by vapor phase processes. It will be apparent that some of these methods can be used in combination, although the matrix of possible combinations is not included.

In certain preferred embodiments of the present invention, the following methods for removing the aluminum oxide layer, alone or in combination, may be used: active solders, rare earth doped alloys, transition metal containing alloys, electrically biased active solders, solder surface tension modification, surface tension modifiers, wetting agents, mechanical removal, scratch pads, ultrasonic soldering, thermal shock, laser ablation, chemical removal, conventional fluxes for aluminum, phosphoric acid fluxes, gaseous fluxes, molten salt fluxes, organic, electrically biased liquid fluxes, catalysis, organic compound dissociation, chemical vapor deposition, aqueous-based chemistry, vapor-phase processes, hydrogen plasma, reverse bias sputter clean/glow discharge, and fast atom bombardment.

These and other preferred embodiments of the present invention will be described in more detail below.

### BRIEF DESCRIPTION OF THE DRAWINGS

FIG. 1 shows a conventional microelectronic assembly including a semiconductor wafer interconnected with a printed circuit board using solder balls.

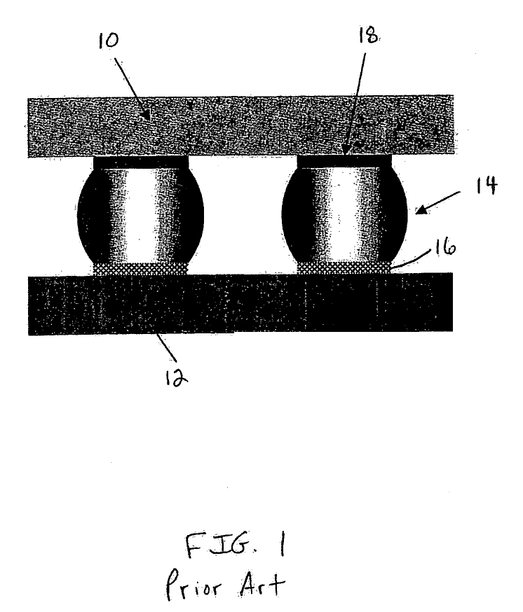

FIG. 2 shows a front elevational view of a C4NP tool for making conductive bumps atop a plate having cavities.

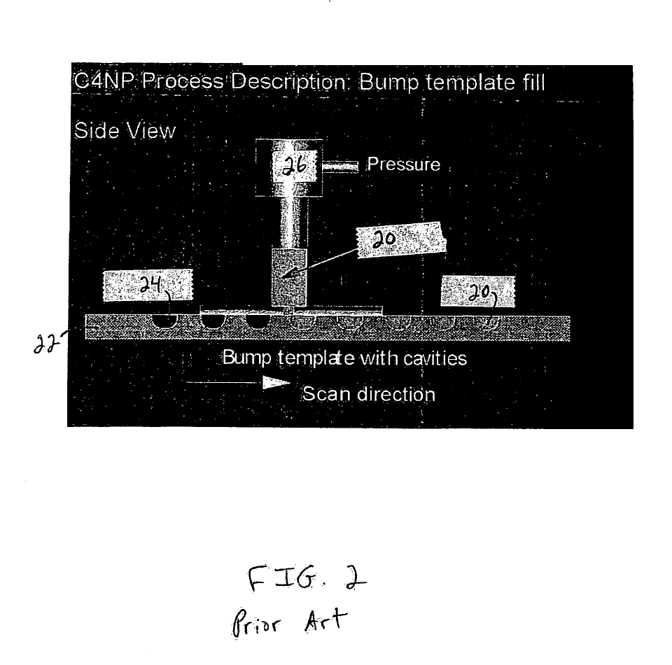

FIGS. 3A-3E show a method of transferring the conductive bumps from the plate shown in FIG. 2 to a microelectronic element.

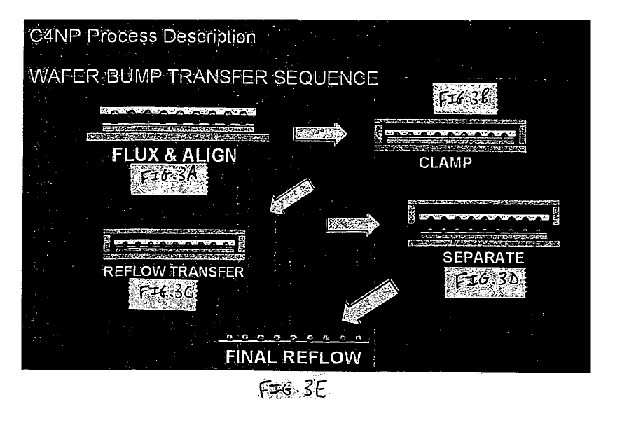

FIG. 4 shows a dispensing tool for a molten metal including a transducer for generating ultrasonic waves in the molten metal, in accordance with certain preferred embodiments of the present invention.

FIGS. 5A and 5B show a method of making a microelectronic assembly, in accordance with further preferred embodiments of the invention.

### DETAILED DESCRIPTION OF PREFERRED EMBODIMENTS

Preferred embodiments of the present invention modify a C4NP tool, or a tool having comparable functionality to a C4NP tool, to apply conductive bumps to the bond pads on a semiconductor wafer or chip. In addition, preferred embodiments of the present invention provide for different metals for a UBM used for flip-chip interconnects than may usually be employed in the prior art.

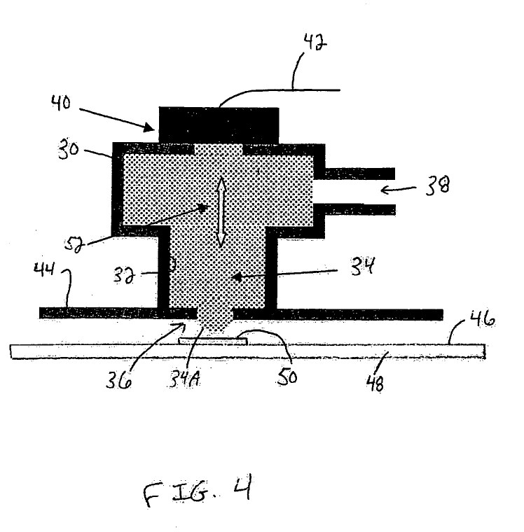

Bond pads on semiconductor wafers are often slightly recessed with respect to the uppermost features, which usually comprise a passivation layer. By placing under a C4NP tool a semiconductor wafer having UBM on the bond pads, each bond pad may be covered in a thin layer of solder. As described above, it has been determined that applying ultrasonic pressure waves to a pool of molten solder when the molten solder is in contact with an oxidized aluminum surface may catalyze wetting. Preferred embodiments of the present invention advantageously employ this finding by modifying a C4NP tool or C4NP-like tool to include an ultra-sonic transducer, or sonode. Referring to FIG. 4, the tool 30 has a chamber 32 for holding a molten metal 34. The tool 30 includes a discharge port 36 at a lower end thereof. The tool 30 includes a pressure port inlet 38, which enables pressurization of the molten metal 34 in the chamber 32. The tool 30 also includes a transducer 40 coupled therewith, and a power line 42 for the transducer 40. The tool may also include a planar element 44 connected with the tool for facilitating alignment of the tool with a front face 46 of a semiconductor wafer 48.

As shown in FIG. 4, the discharge port 36 may be aligned with a conductive pad 50 on the semiconductor wafer 46. While the transducer 40 is activated for applying ultrasonic energy 52 to the molten metal 34, a mass 34A of the molten metal 34 is applied to the contact pad 50. The ultrasonic energy in the molten metal mass 34A effectively breaks up any oxide layer on the conductive pad 50 by mechanical energy. As a result, the bond pads 50 are coated with the molten metal 34, without requiring the use of a flux material or an expensive UBM.

In one particular preferred embodiment, the frequency of operation may be between 20 kHz and 100 MHz, and electrical power applied to the transducer 40 may be between 1 and 300 W of electrical power. The system may use single or multiple frequencies. The amplitude of the displacement produced by the ultrasonic transducer 40 will mostly be in the micron range.

Although the present invention is not limited by any particular theory of operation, it is believed that the tool shown in FIG. 4 allows a low melting point metal in the molten state to wet to the bond pads on a silicon wafer or chip, which in turn allows for UBM metallurgic structures different from that of the prior art. For example, the foundation layer utilized in prior art UBM is not necessarily needed because the low melting point metal is wetted to the aluminum bond pad by virtue of the ultrasonic action. The joint between these two metals will therefore be a metallic bond and ohmic. In addition, there may be no need for the finish layer utilized in prior art UBM.

Conventional solders are usually carefully prepared with very low concentrations of aluminum because even parts per million concentrations may adversely affect the wetting and spreading characteristics. This arises because the aluminum tends to segregate at the surface, where it oxidizes. Some aluminum will always dissolve in any low melting point wetted to it because intersolubility of the constituents is a fundamental requisite for wetting. Provided the UBM is either intrinsically a fusible alloy at the process temperature used to join the solder spheres or is rendered fusible through alloying with one or more of the constituents of the spheres, the metal underlying any oxide skin will melt during attach of the solder spheres. The loss of mechanical support results in the oxide skin fragmenting and being swept out of the joint area where it is no longer an impediment to wetting. In this context a fusible alloy is one where the peak process temperature of the solder sphere attach process lies between its liquidus and solidus temperatures of the alloy.

In an embodiment of the present invention, the low melting point metal for the UBM should be chosen based upon the ability of its contact to the aluminum bond pad to possess sufficient metallurgical stability to survive subsequent processing and for the lifetime of the product. The choice of low melting point metal will vary with the intended application. In many cases, indium, tin, lead, cadmium, bismuth or zinc-based alloys may be suitable. Aluminum has a low solubility in most of these metals and any dissolution that does occur does not always result in the formation of embrittling intermetallic compounds. The ability of the pure metals or simple alloys to act as barriers to inter diffusion and reaction between the aluminum of the bond pad or other metals used on the semiconductor device and the constituents of the solder sphere or PCB land may be improved through the addition of doping elements. The choice may be readily discerned by reference to texts that provide data on alloy phase equilibria and diffusion rates of metals.

Embodiments described herein allow for a flip-chip process that does not use masks or chemical agents for removing oxidation from atop aluminum pads.

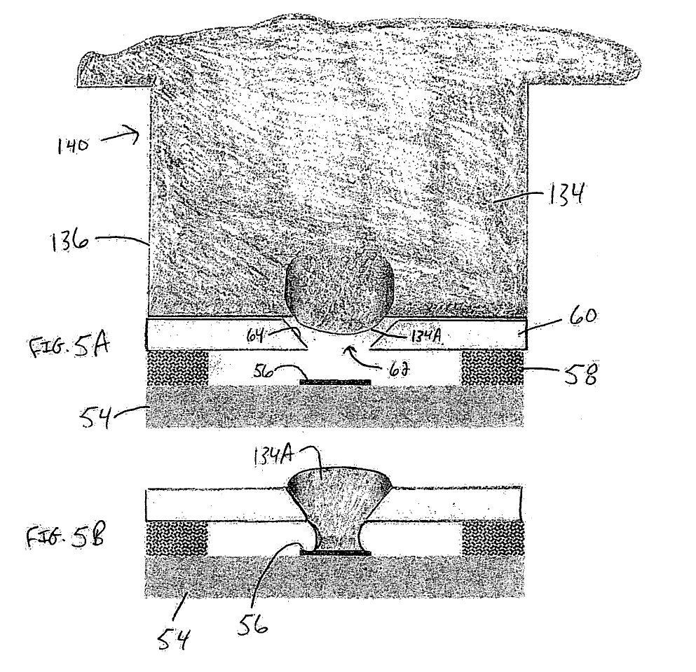

Referring to FIGS. 5A and 5B, in another preferred embodiment of the present invention, a process is used for forming a vertical interconnect structure in a capped chip, as disclosed is commonly assigned U.S. patent application Ser. No. 10/949,674 (TESSERA 3.0-411), the disclosure of which is hereby incorporated by reference herein.

Referring to FIG. 5A, a microelectronic wafer 54 has a number of conductive bonding pads 56 containing UBM formed in an area surrounded by a seal 58. A cap 60, preferably made of glass, ceramic, or silicon, is formed upon seal 58 and has a generally funnel shaped through-hole 62 overlying each pad 56. The side walls of the hole 62 preferably have a coating 64, such as a metal coating, that is wettable by solder. The discharge port 136 of a C4NP tool 140, such as that described above in FIG. 4, is aligned with the opening 62 in the cap 60 and the conductive bonding pad 56. The C4NP tool contains molten metal 134, such as molten solder, preferably under pressure.

Referring to FIGS. 5A and 5B, as the molten metal 134 is subjected to ultrasonic energy, a mass of molten metal 134A is deposited atop the conductive pad 56 of the wafer 54. The mass 134A is preferably released from the discharge port 136 of the tool 140, whereupon the mass 134A wets the coating 64 and drops into its respective hole 62. Additional heat may be applied to cause the mass of molten metal 134A to reflow and move downwardly to connect to conductive pad 56, forming a vertical interconnect structure, as shown in FIG. 5B.

In one preferred embodiment, active solders are used with a C4NP tool. Active solders are conventional solder alloys that contain low concentrations of other elements to provide specific function. That function is usually directed towards enabling or improving the wetting of non-metallic surfaces. Active solders may include rare earth doped alloys, transition metal containing alloys, and electrically biased active solders.

Solders and brazes are sometimes doped with rare earth elements, either individually or in combination. Some of these alloys are commercially available. There are thirty rare earth elements, which is really another name for the elements contained in the Lanthanide and Actinide series of Group Three of the Periodic Table. However, one element of the lanthanide series (promethium) and most of the actinides are trans-uranium elements, that is, man-made and atomically unstable. Rare earth elements have the common attribute that they are extremely reactive towards other metals and most atmospheres. The concentration of the doping addition usually needs to be kept at the parts per million level to avoid unacceptable changes to the melting point or mechanical properties of the solder alloy. When rare earth doped solders are melted on a non-metallic substrate such as alumina, an oxygen exchange reaction occurs whereby the highly active rare earth element strips oxygen from the alumina, effectively reducing the alumina to aluminum and the rare earth metal oxidizes. The oxide of the rare earth distributes through the solder volume as fine particles where they provide dispersion strengthening. In certain preferred embodiments of the present invention, a C4NP tool head is filled with a rare earth doped solder and passed over a silicon wafer having aluminum bond pads for removing the alumina skin and wetting by the doped solder.

A very similar end result to that described above for rare earth doped alloys can be achieved if the solder contains a transition metal of high activity. Titanium is a common choice and again, such alloys are commercially available. The difference with the rare earth doped alloys involves the detail of bonding to the alumina. Transition metals mostly have the ability to form oxides and nitrides of wide stoichiometric range so the result is a graded interface from a covalent bond to the alumina to a metallic bond to the solder. This interfacial layer is usually mechanically quite robust. Some alumina is consumed in this growth of the interfacial, so provided the initial skin of alumina is sufficiently thin, electron tunneling through the remaining oxide thickness can occur, providing a good electrical connection. The principal difference between rare earth and transition metal doped solders is in the process temperature. Transition metal bonding to oxides has a significant temperature dependence so that this approach tends to be reserved for applications involving either higher melting point solders or where a large excess temperature above the melting point of a low point solder can be used.

One of the difficulties of active solders is that under normal circumstances the active ingredients will be distributed throughout the solder volume. However, they are really only required at the solder interface, preferably at high concentrations at this location. This means that the concentration of the active ingredients has to be sufficiently high throughout the solder volume to facilitate wetting to the non-metal component. As mentioned above, high concentrations of active ingredients generally have undesirable side effects on the mechanical properties, melting range and ease of fabricating active solders. One preferred method of circumventing this problem, which could be readily implemented on a C4NP tool head, is to apply an electrical bias to the solder. In an electric field, the active species will diffuse and concentrate at one terminal, usually the anode. Using this method, not only can the concentration of the active ingredients be boosted adjacent to the interface where they are required, but also the bulk of the solder volume is favorably denuded of these elements.

The wetting angle of a molten solder droplet on a solid surface is a reasonably well-understood science. Under normal circumstances, the contact angle between a molten solder droplet and a non-wettable surface will tend towards 180 degrees. As a result, the area of contact is very small. Although the solder in the reservoir of a C4NP tool is under slight positive pressure, on a macroscopic scale, surface tension forces are considerably larger and will always work to minimize the contact area. A naturally grown thin film of alumina on aluminum is seldom free of defects. If a molten solder is able to breach a fissure in the skin, wetting to the underlying aluminum will occur and the alumina skin will be undermined and lifted off. There are two known methods of altering the apparent surface tension force between a molten solder and an alumina surface that will enable a conventional solder to take advantage of defects in the oxide film to initiate wetting of the bond pads.

A first factor that determines the wetting angle of a molten solder on a solid surface is the surface tension of the liquid droplet. The surface tension of a molten solder can be lowered by the addition of certain metals. Bismuth is particularly effective in this regard and this is one of the reasons for the inclusion of this element, at low concentrations, in many of the “lead-free” solder alloys that are commercially available. For this reason, bismuth, at the parts per million concentration, is an essential ingredient in low melting point aluminum-based brazes that are used to fabricate aluminum heat exchangers in fluxless processes. The exact mechanism of how the bismuth works has not been fully elucidated, but clearly a solder with a lower surface tension will wet and spread more easily than one with high surface tension. Thus, this method may be combined with one of the others described in this invention to facilitate easy and consistent wetting of the aluminum bond pads on a wafer.

In other preferred embodiments of the present invention, wetting of a molten solder on a non-metallic or oxidized surface may be improved by incorporating gallium. The mechanism is not a true change in surface tension as the wetting is a result of the formation of an alumina/gallium oxide interfacial film. However, again from the perspective of a C4NP tool head, the use of a gallium containing alloy will improve contact between the molten solder and the bond pads and hence the possibility of initiating wetting through a fissure or other defect in the alumina layer. Similarly, if gallium is added to an activated solder, it again encourages the molten alloy to contact the entire bond pad area so that the active ingredients can work, rather than for wetting to have to be propagated from the point of first contact. Gallium and bismuth are not exclusive additions and may beneficially be added to active alloys in combination.

One preferred method of circumventing the problem of wetting to the aluminum bond pads, on account of the native alumina film, is to mechanically remove the film and contact the underlying metal with molten solder before the film has had a chance to regrow. Because the regrowth of the alumina film starts instantaneously, the removal of the oxide must be completed just an instant before the C4NP tool head containing the molten solder passes over.

As discussed above, it is not necessary to completely remove the alumina film to initiate the wetting process. It is sufficient to simply provide a few sites where metal-to-metal contact can occur to start the process. In one preferred embodiment of the present invention, a C4NP tool has an element on its leading edge to lightly “scratch” the aluminum bond pads immediately ahead of the slot containing the pressurized solder reservoir. Because the alumina layer is relatively thin, the mechanical scratching may be induced by a relatively soft material, so that the remainder of the wafer surface is not damaged by contact with the scratching element. It is well known that carbon and glass fiber brushes will disrupt surface oxide films on many metals and are actually recommended as a mechanical pre-treatment for solder alloys prior to fluxless soldering. Brushes of this type are likely to be suitable for this purpose.

In another preferred embodiment of the present invention, the C4NP tool may be coupled with an ultrasonic device for applying ultrasonic energy to the molten metal, which in turn strips away the alumina film as it is deposited atop a conductive bond pad, as described above in more detail.

Aluminum and alumina have markedly different coefficients of thermal expansion, the differences being in the region of 15 ppm/k. Thus, when an aluminum component is subject to a very rapid change in temperature, the oxide film will crack and craze until such a time as the exposed aluminum can react with the air and repair its protective film. The temperature change may be positive or negative and both are referred to as “thermal shock.” In certain preferred embodiments of the present invention, if molten solder is placed in contact with the bond pad either during or after thermal shock of the wafer, then the temporary defects in the alumina film may be exploited to propagate wetting of the entire bond pad. Thus, the present invention contemplates subjecting the bond pads on the wafer to sufficient thermal shock to crack and craze the oxide film. In certain preferred embodiments, this may be a natural consequence of the passage of a C4NP tool containing molten solder over the wafer surface. Any amplification of the magnitude of the temperature change between the molten solder and the wafer will be beneficial. In one particular preferred embodiment, the wafer may be cooled to a temperature below room temperature, and the solder may be super-heated. In another preferred embodiment, a higher melting point solder may be employed. The latter may be a natural consequence of the selection of a suitable alloy to wet to the bond pads. For example, zinc alloys in general have much higher melting points than tin-based solders. In still other preferred embodiments, the bond pads on the wafer may be subjected to thermal shock by a separate heater, achieved by hot gas, an optical furnace or laser beam, again immediately in advance of the reservoir of the C4NP tool containing the molten solder.

In another preferred embodiment, laser ablation may be used. Lasers can achieve very high energy densities through a combination of the net power input and small diameter of the focal spot that can be produced. Indeed, lasers have the ability to ablate alumina and laser cutting of alumina ceramic is a widely practiced industrial technology. Thus, in certain preferred embodiments of the present invention, a C4NP tool may be modified so that the alumina film is ablated from the bond pads immediately prior to the passage of the head containing the molten solder reservoir. The modification may include providing an optical window in the leading edge of the C4NP tool. The method may utilize a map of the bond pads on each wafer so that the laser may be programmed to only ablate a surface film from those areas.

Although alumina is generally perceived to have good chemical stability, there exist chemical agents that can dissolve, reduce and form complexes with it. in a manner that facilitate removal of the alumina layer. In certain preferred embodiments, the C4NP tool head may be modified to carry another reservoir for the chemical agents located immediately ahead of the discharge opening for the molten metal or solder.

Although conventional soldering fluxes are unable to cope with the native film on aluminum, fluxes that can satisfy this requirement are commercially available. There are basically two types—organic fluxes and chloride-based fluxes. The fluxing mechanism is essentially the same, namely one involving an exchange reaction whereby aluminum atoms in the oxide are replaced by another metal, typically zinc, tin or cadmium. This chemical reaction destabilizes the inertness of the oxide film, either rendering it sufficiently metallic to be electrically conductive, enabling it to be dissolved in the solder, or simply undermined and displaced by the bulk solder. One major problem with these fluxes is that, under normal conditions, the effectiveness of the fluxing action is extremely sensitive to the humidity of the atmosphere. In relatively moist atmospheres, a significant portion of the flux is rendered ineffective through hydrolization, thereby making the process difficult to control. Although the present invention is not limited by any particular theory of operation, it is believed that this problem may be solved by containing the flux in a sealed chamber, such as a chamber on a C4NP tool. Thus, in certain preferred embodiment, a conventional flux for aluminum may be used on a double-headed machine, the first reservoir containing a conventional flux for aluminum and the second a standard solder alloy.

In another preferred embodiment, phosphoric acid fluxes may be used. Phosphoric acid is an extremely effective flux for many metal oxides, including stainless steel. To date, its use has been restricted to low temperature, indium-based solders because it polymerizes when heated in air above about 200° C. In certain preferred embodiments of the present invention, a phosphoric acid is contained in a sealed chamber of a C4NP tool, which enables the temperature of the acid to be sufficiently elevated so that it is compatible with other solder alloys. The elevated temperature will also boost its chemical activity sufficiently to deal with aluminum oxide.

Certain reactive gases are able to remove oxide films from metal surfaces by chemical reduction. Reactive atmospheres that have been reported in the literature include formic acid and acetic acid vapor, carbon monoxide and halogen gasses. Some of these are sufficiently active to be able to reduce indium oxide, which is comparable in its chemical stability to alumina. Because the action of the gas would be to reduce the surface oxide to metal, it is important that this process is performed immediately before the solder is applied to the bond pads on the wafer. Thus, in certain preferred embodiments of the present invention, a dual-chamber C4NP tool may be used including a first reservoir and slot containing a gaseous flux atmosphere and a second chamber containing the solder alloy.

Molten salts are widely used as brazing fluxes, but not commonly as soldering fluxes. The reason for this is a combination of the corrosive nature of the constituents, even at room temperature and the absence of salt mixtures suitable for use with lead-tin solders. However, by reference to the relevant phase diagrams it will be apparent that there exist low melting point eutectics and other transition reactions between halogenated alkali-earth metal compounds that can be used at the higher end of the temperature range of normal soldering practice (>300° C.). Molten salt fluxes will dissolve metal oxides to leave a clean metal surface. The alkali-halogen mixtures have a further benefit in that the residues are water-soluble and so may easily be removed from the wafer after processing. In certain preferred embodiments of the present invention, for application to a wafer, a dual head C4NP tool may be used with the molten salt flux in the first reservoir and molten solder in the second reservoir. As explained previously, because the salt flux process leaves a fresh metallic surface, the surface is preferably wetted by solder as soon as possible and preferably in less than 1 second after preparation to prevent reoxidation through contact with the atmosphere. The requirement is readily met by a double-headed C4NP or C4NP-like tool.

Certain organic compounds possess the ability to dissolve metal oxides. For example it is known that molten acetamid will dissolve both aluminum and magnesium oxides. Indeed, this compound is the only known flux for magnesium and its alloys, which are traditionally classed as an “unsolderable” metal. Acetamid melts at 83° C. Thus, in one preferred embodiment of the present invention, a dual headed C4NP machine may be used to apply the material to the bond pads on the wafer. The difference between this method and that described above for molten salt fluxes is that the application temperature may be substantially lower, which may offer benefits in terms of thermal design of the C4NP tool.

Generally, the liquid or molten fluxes discussed above have one constituent, which is often the predominantly active component that is a highly polar material, i.e. ionic. As a result, the flux will respond to an electric field. As discussed above for electrically biased active solder, application of an electric filed between the bond pad on the wafer and the bulk of the -flux medium may concentrate the active ingredient at the desired interface, with a consequential improvement in the efficacy of fluxing.

The objective of the soldering process is to apply a film of a fusible metal to the aluminum bond pads on a silicon wafer or chip. Over the years, some ingenuity has been applied to fulfilling this need on printed circuit boards, some of which may be adopted for this application. These protocols generally work by using the material on the land or bond pad to catalyze a deposition reaction that results in the deposition of a different metal on top.

There are certain chemical compounds that may be catalyzed by reaction with copper oxide to deposit metal. One example is the lead salts of various organic acids that are used to “tin” the copper bond pads on printed circuit boards prior to a surface mount assembly process. On heating, the salt decomposes, thereby liberating an acid that fluxes the copper to clean the copper surface. To make the process selective, the compound is designed so that deposition occurs at much lower temperatures when in contact with copper oxide than in the bulk material. The unused compound is simply removed from the board surface and recycled. In certain preferred embodiments of the present invention, the above-described methods may be used on wafers having copper bond pads and alternative chemical compounds may be identified that are compatible with aluminum oxide. In certain preferred embodiments, the lead-based salts are in the form of a dry powder and are preferably mixed in a suitable carrier agent for dispensing via a C4NP tool. In other preferred embodiments, the process may be carried out on a wafer scale.

In chemical vapor deposition processes, an organo-metallic gas is forced to decompose by either a catalyst-initiated reaction with the substrate or thermally by a heated substrate. The temperatures for many such processes are in the range 200-400° C. and are therefore compatible with processed semiconductor wafers. Some chemical vapor deposition processes involve oxidation of halides and are therefore especially suitable where there is a thin film of alumina on the substrate, i.e. aluminum bond pads that must be tinned and have an oxide skin removed during the deposition process. Many chemical vapor deposition processes are performed at about atmospheric pressure and would therefore be compatible with a dual head C4NP tool. Low temperature chemical vapor deposition of nickel is an industry-standard process that is a key step in the fabrication of foam metal. Nickel is a common ingredient of many UBMs and would therefore be an ideal candidate for deposition by this method, in accordance with certain preferred embodiments of the present invention.

Immersion plating, electroless plating and electroplating of aluminum are all well-known technologies. Indeed, one low cost method of applying UBM to semiconductor wafers is by electroless plating of zinc, then nickel, then gold. The zincating step is not a conventional layer deposition but actually an exchange reaction with aluminum that results in displacement of the oxide film. Although wet plating is traditionally performed in large tanks, plating of semiconductor wafers is more often done in single cells for achieving better uniformity of the deposits across the wafer surface, which also decreases the consumption of chemicals. Many wet plating chemicals and effluent are not environmentally friendly. An inherent aspect of the design of the C4NP tool head of the present invention is that it forms a seal to the wafer around the slot at the bottom of the reservoir. The seal is necessary to prevent the egress of molten solder, which is under pressure, and ingress of air and other contaminants. Although molten solder has a higher surface tension than aqueous based solutions, in certain preferred embodiments of the present invention, the C4NP tool head may be modified with compliant gaskets or other structure to form a seal that is strong enough to hold aqueous-based chemicals in the reservoir. Thus, a new plating apparatus is contemplated whereby solutions are passed sequentially across the surface of the part to be coated, each being contained in a separate reservoir. Depending on the chemistry and type of plating selected, the modified C4NP tool head may need a number of reservoirs and slots or multiple tools could be used.

In other preferred embodiments of the present invention, the integrity of the seal between the C4NP tool head and the silicon wafer may be improved for offering the possibility of vapor phase processing to deal with the oxide film on the aluminum bond pads. Vapor phase processes generally operate in reduced pressure environments. As an alternative to achieving a local seal underneath a C4NP head, in certain preferred embodiments of the present invention, the wafer and the C4NP tool head may be placed in a chamber that is evacuated to the pressure required for the particular process. Using either approach, there exist a number of known industrial process that could be used facilitate wetting of the bond pads by molten solder.

Molecular hydrogen is inert towards alumina except under the most extreme of conditions. Hydrogen gas cannot therefore chemically reduce alumina to aluminum. However, if the hydrogen molecules are split into ions, the division process effectively imparts additional energy to the species and direct reduction of many metal oxides at normal soldering temperatures becomes practicable. Atomic hydrogen reacts with surface oxides to form hydroxides, water vapor and hydrogenated complexes that are volatile and can be easily removed from the joint area. Soldering ovens equipped with hydrogen plasma generators are sold commercially. Hydrogen plasmas can be generated by a variety of means including heated filaments, microwave sources, photo dissociation and low frequency alternating current ionization. The concentration of atomic hydrogen decays rapidly with distance from the source. Thus, in certain preferred embodiments of the present invention, a C4NP tool head that generates the active species directly above the wafer may be used for removing alumina from the bond pads on the wafer. As described previously, the solder head of the C4NP tool may be required to rapidly follow the cleaning treatment to minimize the reoxidation of the aluminum when no longer in direct sight of gas containing hydrogen gas at sufficient concentration.

Another known method of removing the surface layers from material is reverse bias sputtering. The process works irrespective of whether the surface layers are metallic or non-metallic. In its simplest form, the sample is placed in a low-pressure atmosphere and a very high electrical field gradient is established immediately adjacent to the sample surface. This has the effect of ripping atoms out of the surface literally one by one. If the surface is aluminum covered with a layer of alumina, the oxide is removed first followed by the metal. One of the elements of successful control of this process is to know when to stop the cleaning and hence the general consistency of semiconductor wafers will be a benefit in this regard. The speed at which reverse bias sputter cleaning, or “glow discharge cleaning” as it is sometimes also called, occurs depends on a host of interrelated factors. However, it is a well-understood process. The main difficulty with its incorporation in a C4NP tool is that it is a relatively slow process, taking minutes rather than seconds to remove a native alumina film from aluminum. In certain preferred embodiments of the present invention, a C4NP tool and substrate holder are housed in a low pressure chamber and the entire wafer is stripped of oxide before a pass is made with the C4NP tool to apply solder. For the reasons given above, it is important that the solder is wetted to the aluminum as soon as possible after cleaning and clearly without breaking the seal on the low pressure chamber in the interim.

Yet another preferred method of removing the top surface layers of material in a controlled manner is fast atom bombardment. In this process, argon ion are accelerated and then rendered electrically neutral before being allowed to impinge on the surface to be cleaned. The gas stream is usually at an inclined angle to the wafer surface. The effect is akin to a using miniature hammers as the argon atoms effectively “chip” atoms from target surface on a one-to-one basis. As with the reverse bias sputter clean process described above, fast atom bombardment is a relatively slow process and requires a low pressure atmosphere to operate. In certain preferred embodiments, a C4NP tool head and wafer holder are enclosed in a chamber and the wafer is stripped of oxide before the solder is applied.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of making a microelectronic assembly comprising:
providing a microelectronic element having a front face and contact pads accessible at the front face;
dispensing a mass of molten metal onto one of the contact pads of said microelectronic element;
applying ultrasonic waves to the mass of molten metal during the dispensing step for facilitating wetting of the mass of molten metal with the one of the contact pads of said microelectronic element.

2. The method as claimed in claim 1, further comprising modifying the frequency of the ultrasonic waves applied to the molten metal.

3. The method as claimed in claim 1, wherein the dispensing step comprises:
providing a dispensing tool containing a molten metal, said tool having a discharge port for dispensing the molten metal; and
aligning the discharge port of said dispensing tool with the one of the contact pads of said microelectronic element and dispensing the mass of the molten metal through the discharge port and onto the one of the contact pads of said microelectronic element.

4. The method as claimed in claim 1, further comprising repeating the dispensing step for dispensing a mass of molten metal atop a plurality of the contact pads of said microelectronic element.

5. The method as claimed in claim 3, wherein said dispensing tool comprises:
a chamber for holding the molten metal, the chamber being in communication with the discharge port;
an ultrasonic transducer coupled with said chamber for producing the ultrasonic waves.

6. The method as claimed in claim 3, further comprising:
providing a planar element over the front face of said microelectronic element, said planar element having at least one opening extending therethrough;
aligning the at least one opening in said planar element with the one of the contacts of said microelectronic element;
aligning the discharge port of said dispensing tool with the at least one opening in said planar element.

7. The method as claimed in claim 6, wherein said planar element is connected with said microelectronic element.

8. The method as claimed in claim 6, wherein said planar element is connected with said dispensing tool.

9. The method as claimed in claim 6, wherein said microelectronic element is selected from the group consisting of semiconductor wafers, semiconductor chips and circuitized substrates.

10. The method as claimed in claim 1, wherein said ultrasonic pressure waves have a frequency of about 20 KHz-100 MHz.

11. The method as claimed in claim 5, wherein said ultrasonic transducer generates ultrasonic waves having a frequency of about 20 KHz-100 MHz.

12. The method as claimed in claim 3, further comprising:
connecting an ultrasonic transducer with said dispensing tool; and
operating said ultrasonic transducer during the dispensing step.

13. The method as claimed in claim 12, wherein said ultrasonic transducer is coupled with the discharge port of said dispensing tool.

14. The method as claimed in claim 3, wherein said dispensing tool has a C4NP-like configuration and at least one ultrasonic transducer coupled with said dispensing tool.

15. The method as claimed in claim 14, wherein said at least one ultrasonic transducer includes a controller for modifying the frequency of the ultrasonic waves generated by said at least one ultrasonic transducer.

16. The method as claimed in claim 1, wherein the contact pads of said microelectronic element comprise aluminum.

17. The method as claimed in claim 17, wherein the contacts of said microelectronic element further comprise a low melting point metal applied atop the aluminum pads.

18. The method as claimed in claim 17, wherein the low melting point metal is a fusible alloy.

19. The method as claimed in claim 18, wherein the fusible alloy is a pure metal or an alloy comprising indium, tin, lead, cadium or zinc.

20. A method of making a microelectronic assembly comprising:
providing a microelectronic element having a front face and contact pads accessible at the front face;
providing a dispensing tool containing a molten metal and having a discharge port for dispensing the molten metal;
aligning the discharge port of said dispensing tool with one of the contact pads of said microelectronic element;
dispensing a mass of the molten metal through the discharge port and onto the one of the contact pads of said microelectronic element; and
applying ultrasonic waves to the mass of molten metal during the dispensing step for facilitating wetting of the mass of molten metal with the one of the contact pads of said microelectronic element.

21. The method as claimed in claim 20, wherein said dispensing tool has a C4NP configuration.

22. The method as claimed in claim 20, further comprising pressurizing the molten metal within said dispensing tool prior to the dispensing step.

23. The method as claimed in claim 20, wherein the applying ultrasonic waves step comprises applying ultrasonic waves at a frequency of around 20 kHz to 100 MHz.

24. The method as claimed in claim 20, wherein said dispensing tool comprises:
a chamber for holding the molten metal, the chamber being in communication with the discharge port; and
an ultrasonic transducer in contact with said dispensing tool for producing ultrasonic waves in the chamber.

25. The method as claimed in claim 20, further comprising:
providing a planar element over the front face of said microelectronic element, said planar element having at least one opening extending therethrough;
aligning the at least one opening in said planar element with the one of the contacts on said microelectronic element;
aligning the discharge port of said dispensing tool with the at least one opening extending through said planar element.

26. The method as claimed in claim 25, wherein said planar element is connected with said microelectronic element.

27. The method as claimed in claim 25, wherein said planar element is connected with said dispensing tool.

28. The method as claimed in claim 20, wherein said microelectronic element is selected from the group consisting of semiconductor wafers, semiconductor chips and circuitized substrates.

29. The method as claimed in claim 20, further comprising:
connecting an ultrasonic transducer with said dispensing tool; and
operating said ultrasonic transducer during the dispensing step for applying ultrasonic waves to the mass of molten metal.

30. The method as claimed in claim 29, wherein said ultrasonic transducer is coupled with the discharge port of said dispensing tool.

31. The method as claimed in claim 20, further comprising dispensing a mass of the molten metal onto a plurality of the contact pads of said microelectronic element.
